(19) United States
(12) Patent Application Publication
(10) Pub. No.: US 2009/0101921 A1
(43) Pub. Date: Apr. 23, 2009

(54) LED and thermal conductivity device combination assembly

(75) Inventor: Yaw-Huey Lai, Taipei County (TW)

Correspondence Address: BACON & THOMAS, PLLC, 625 SLATERS LANE, FOURTH FLOOR, ALEXANDRIA, VA, 22314-1176, US

(73) Assignee: TAI-SOL ELECTRONICS CO., LTD., TAIPEI CITY (TW)

(21) Appl. No.: 11/987,821

(22) Filed: Dec. 5, 2007

(30) Foreign Application Priority Data
Oct. 17, 2007 (TW) 96217382

(51) Int. Cl. H01L 33/00

(52) U.S. Cl. 257/88; 257/99; 257/E33.075

(57) ABSTRACT

AN LED and thermal conductivity device combination assembly includes a thermal conductivity device, two conducting members each having a metal conducting wire and an insulator surrounding the metal conducting wire and attached to the thermal conductivity device, LED chips each having a positive electrode and a negative electrode disposed at the top side and an insulation layer disposed at the bottom side and bonded to the surface of the thermal conductivity device, lead wires connected between the positive electrode and negative electrode of the LED chips and the metal conducting wires of the conducting members to connect the LED chips in series and in parallel, and a packaging device covering the LED chips.

### BACKGROUND OF THE INVENTION

1. Field of the Invention

The present invention relates to LED (light emitting diode) and heat dissipation technology and more particularly, to an LED and thermal conductivity device combination assembly.

2. Description of the Related Art

High brightness LEDs (light emitting diodes) produce much heat energy during operation. Therefore, how to solve heat dissipation problem during light emitting operation of LEDs is an important subject to people in this art. Taiwan Patent M313,759 discloses a technique of installation of LED chips in a heat sink for direct transfer of heat energy from the LED chips to the heat sink for quick dissipation.

The aforesaid Taiwan Patent M313,759 solves heat the dissipation problem, however because the negative electrodes of the LED chips are directly installed in the heat sink, the LED chips are arranged in a parallel status when their positive electrodes are connected to a circuit.

When all the LED chips are arranged in parallel, the total resistance is greatly reduced, requiring a low voltage and a high current. If the number of the LED chips is increased, the demand for current will be relatively increased while the demand for voltage remains unchanged. This condition will cause a trouble in the control of the driving power, i.e., it is difficult to satisfy the demand for low voltage and high current. Further, this arrangement will also cause extra heat energy, wasting much heat dissipation resource.

### SUMMARY OF THE INVENTION

The present invention has been accomplished under the circumstances in view. It is one object of the present invention to provide an LED and thermal conductivity device combination assembly that has LED chips installed in a thermal conductivity device and arranged in series, or in series and in parallel, providing excellent heat dissipation effect and facilitating the control of the driving power.

It is another object of the present invention to provide an LED and thermal conductivity device combination assembly, which has the positive electrodes and negative electrodes of the LED chips be connected to conducting members for easy installation.

To achieve this and other objects of the present invention, the LED and thermal conductivity device combination assembly comprises a thermal conductivity device; at least one pair of conducting members, the conducting members each comprising a metal conducting wire and an insulator, the insulator being attached to the thermal conductivity device to insulate the metal conducting wire from the thermal conductivity device; a plurality of LED units, the LED units each comprising an LED chip, the LED chip of each of the LED units comprising a positive electrode and a negative electrode disposed at a top side thereof and an insulation layer disposed at a bottom side thereof and bonded to the surface of the thermal conductivity device; a plurality of lead wires connected between the positive electrode and negative electrode of the LED chip of each of the LED units and the metal conducting wires of the conducting members to connect the LED chips of the LED units in series and in parallel; and at least one packaging device covering the LED units. By means of the aforesaid arrangement, LED chips are installed in a thermal conductivity device in a series manner to achieve excellent heat dissipation effect and to lower power specification requirement. Further, the arrangement of the conducting members facilitates installation of the LED and thermal conductivity device combination assembly.

### BRIEF DESCRIPTION OF THE DRAWINGS

FIG. 1 is an elevational assembly view of an LED and thermal conductivity device combination assembly in accordance with a first embodiment of the present invention.

FIG. 2 is a top view of the LED and thermal conductivity device combination assembly in accordance with the first embodiment of the present invention.

FIG. 3 is a side view of the LED and thermal conductivity device combination assembly in accordance with the first embodiment of the present invention.

FIG. 4 is an enlarged view of a part of FIG. 3, showing connection arrangement of one series of LEDs.

FIG. 5 is an elevational assembly view of an alternate form of the first embodiment of the present invention, showing circuit boards used for the conducting members.

FIG. 6 is an elevational assembly view of an LED and thermal conductivity device combination assembly in accordance with a second embodiment of the present invention.

FIG. 7 is a side view of the LED and thermal conductivity device combination assembly in accordance with the second embodiment of the present invention.

### DETAILED DESCRIPTION OF THE INVENTION

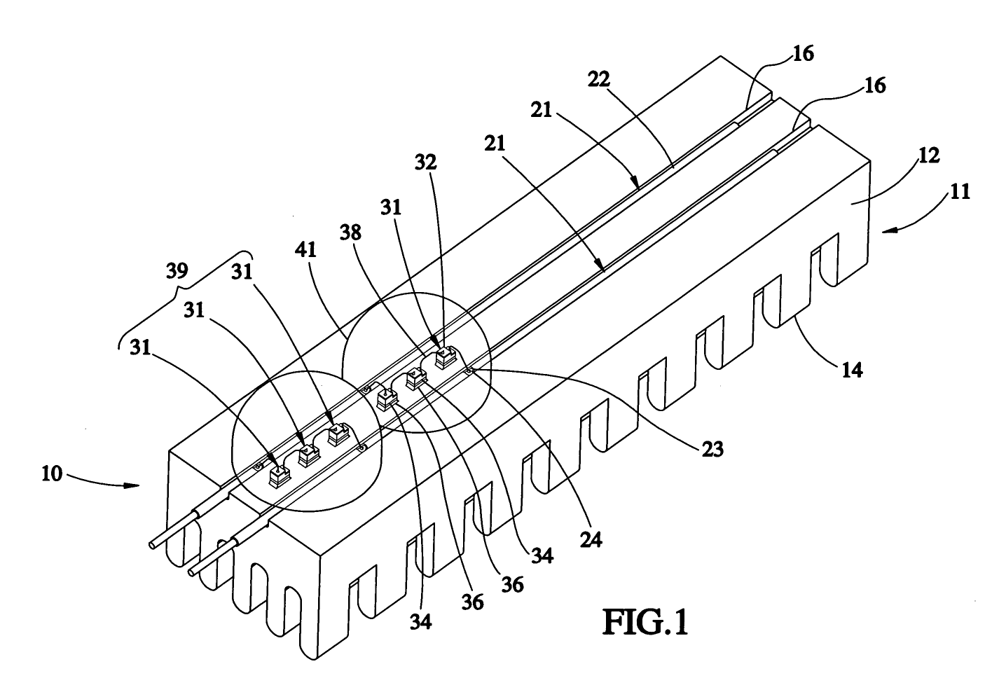

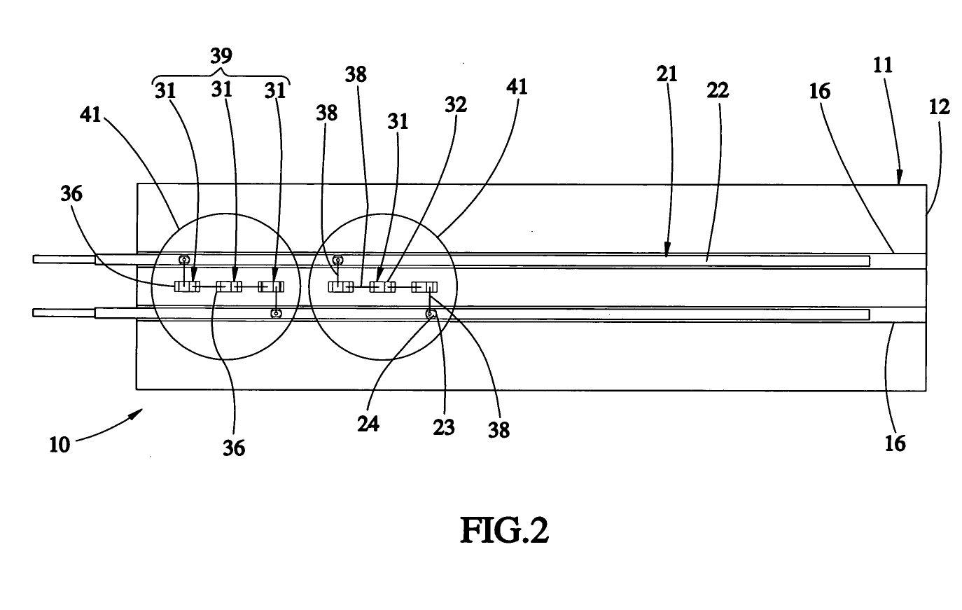

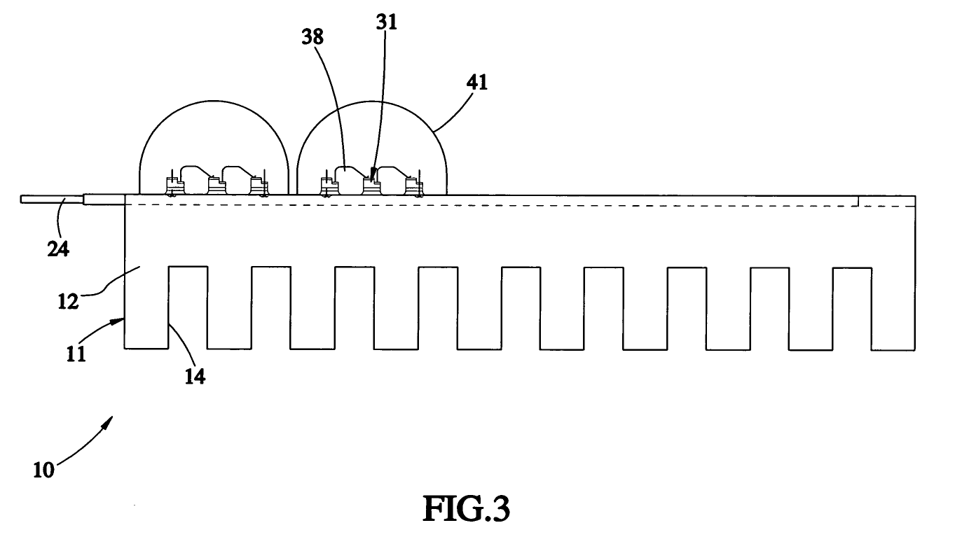

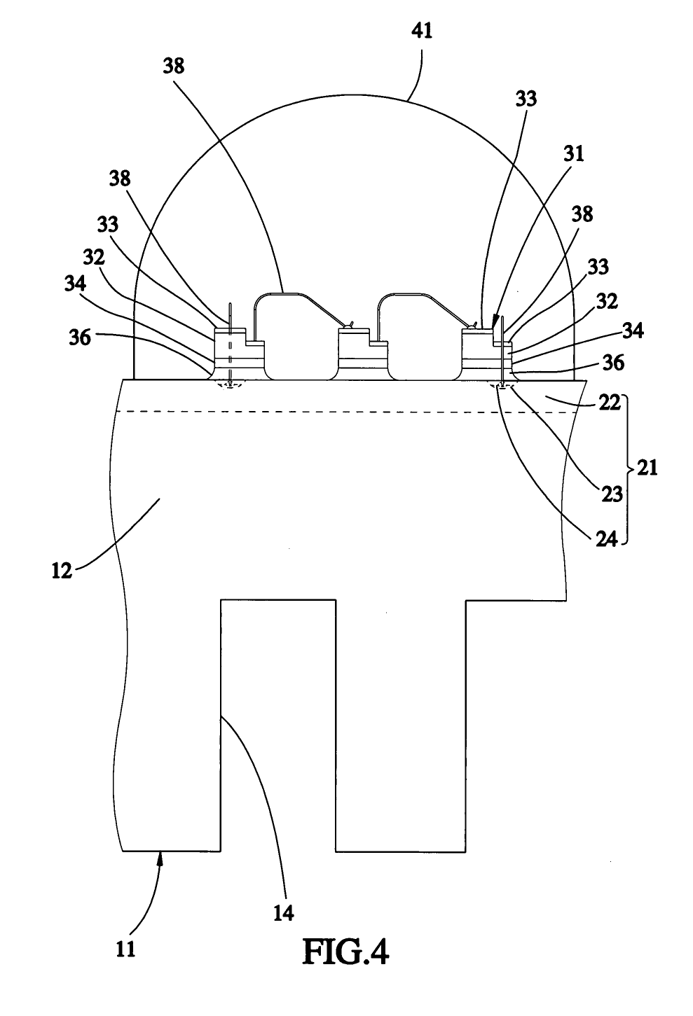

Referring to FIGS. 1-4, an LED and thermal conductivity device combination assembly 10 in accordance with a first embodiment of the present invention is shown comprised of a thermal conductivity device 11, two conducting members 21, multiple LED units 31, and two packaging devices 41.

The thermal conductivity device 11 is a heat sink, comprising a thermal transfer plate 12 and a plurality of radiation fins 14 arranged on the top surface of the thermal plate 12. The thermal transfer plate 12 has two grooves 16 on its bottom surface.

The conducting members 21 are respectively set in the grooves 16 on the thermal transfer plate 12, each comprising a metal conducting wire 24 and an insulator 22 surrounding the metal conducting wire 24. The insulator 22 of each conducting member 21 has at least one opening 23 that exposes the associating metal conducting wire 24. The insulator 22 isolates the associating metal conducting wire 24 from the thermal conductivity device 11.

The LED units 31 are arranged adjacent to the conducting members 21, each comprising an LED chip 32 and at least one lead wire 38. Each LED chip 32 has two electrodes 33 arranged at the top. The two electrodes 33 include a positive electrode and a negative electrode. The LED chip 32 has a bottom insulation layer 34 bonded to the bottom surface of the thermal conductivity device 11 by means of a thermal conductivity layer 36. The thermal conductivity layer 36 can be solder paste or epoxy resin. The electrodes 33 are respectively connected with a respective lead wire 38. The LED units 31 are arranged into two LED series sets 39. In each LED series set 39, the positive electrode of one LED chip 32 is connected to the negative electrode of another LED chip 32 with one lead wire 38. Further, the negative electrode of one LED chip 32 of one LED series set 39 is connected to the metal conducting wire 24 of one conducting member 21 with one lead wire 38 that extends through one opening 23 on the insulator 22 of the associating conducting member 21. The positive electrode of one LED chip 32 of the same LED series set 39 is connected to the metal conducting wire 24 of the other conducting member 21 with one lead wire 38 that extends through one opening 23 on the insulator 22 of the associating conducting member 21. Therefore, the two LED series sets 39 are connected in parallel to the conducting members 21, i.e., the LED units 31 coupled together in a series and parallel coexist manner.

The packaging devices 41 cover the LED units 41 of the two LED series sets 39 respectively, and also cover a part of the conducting members 21.

In actual practice, an imaginary line should be used to indicate the packaging devices 41. However, for better indication, a solid line is used in the drawings to indicate the packaging devices 41.

As indicated above, the LED chips 32 of the LED units 31 are arranged into multiple LED series sets 39. This arrangement increases the demand for voltage at the two ends without increasing the demand for current. Therefore, the invention facilitates the control of the driving power, avoiding the trouble of high current output. Further, because the series connection of the LED chips 32 in each LED series set 39 does not require a high current, the LED and thermal conductivity device combination assembly 10 does not produce much heat energy upon connection of electric current. In consequence, the LED and thermal conductivity device combination assembly 10 has excellent heat dissipation efficiency. Further, by means of the two conducting members 21, the LED series sets 39 can be connected in parallel, allowing the maker to adjust the power requirement.

Further, because each LED chip 32 has the respective bottom insulation layer 34 bonded to the bottom surface of the thermal conductivity device 11 by means of a thermal conductivity layer 36, heat energy that is produced during operation of the LED chips 32 is transferred rapidly from the LED chips 32 through the thermal conductivity layer 36 to the thermal conductivity device 11 for quick dissipation into the outside open air by the radiation fins 14.

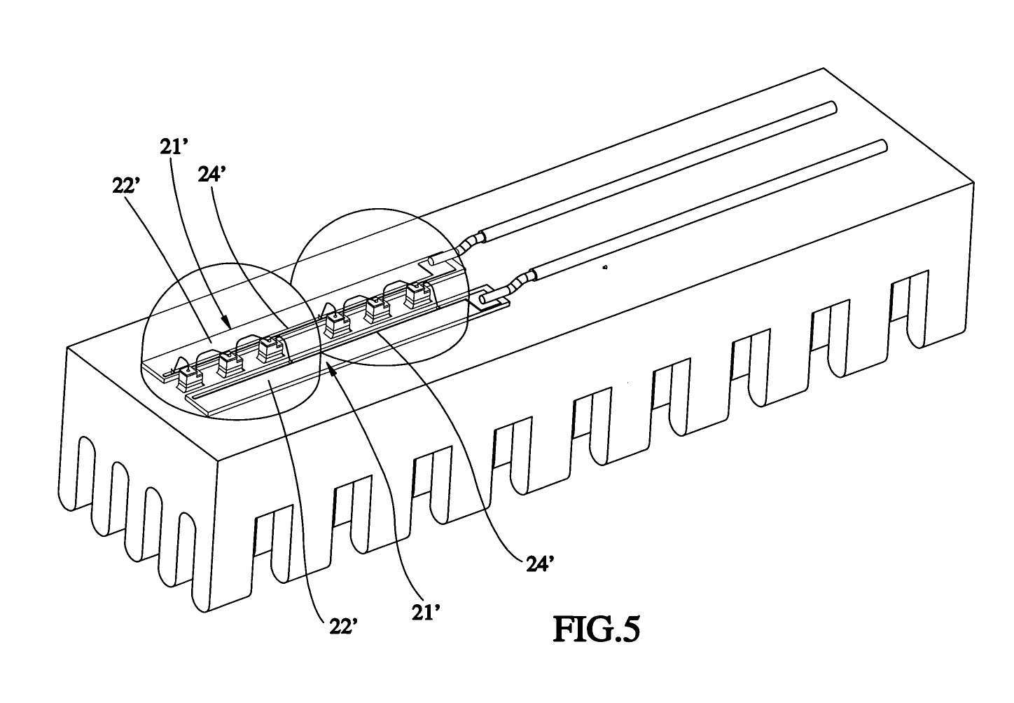

Referring to FIG. 5, the conducting members 21′ can be circuit boards, the insulator 22′ can be epoxy resin at the bottom side of the circuit board, and the metal conducting wire 24′ can be a copper foil on the circuit board.

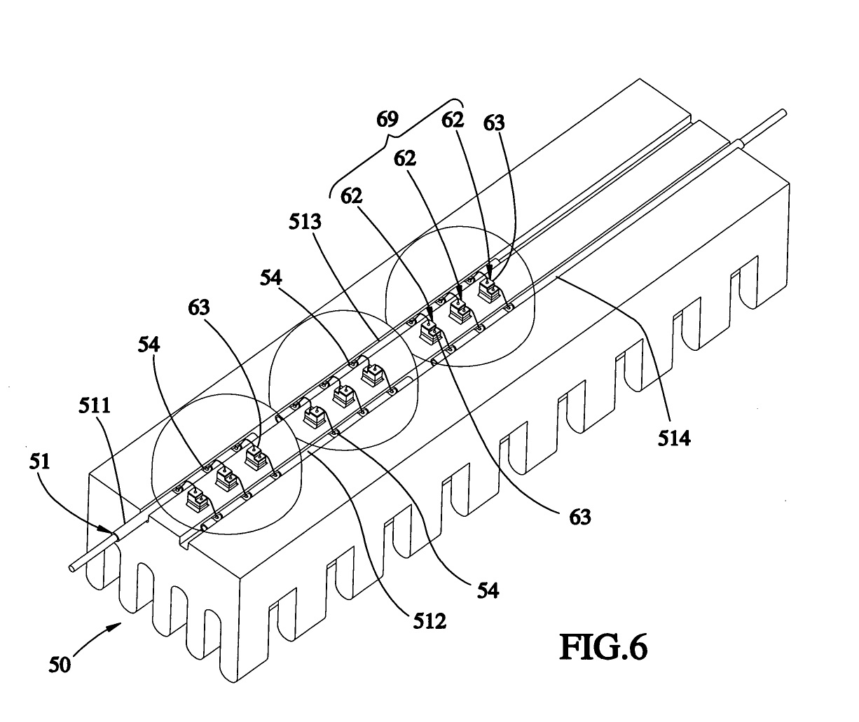

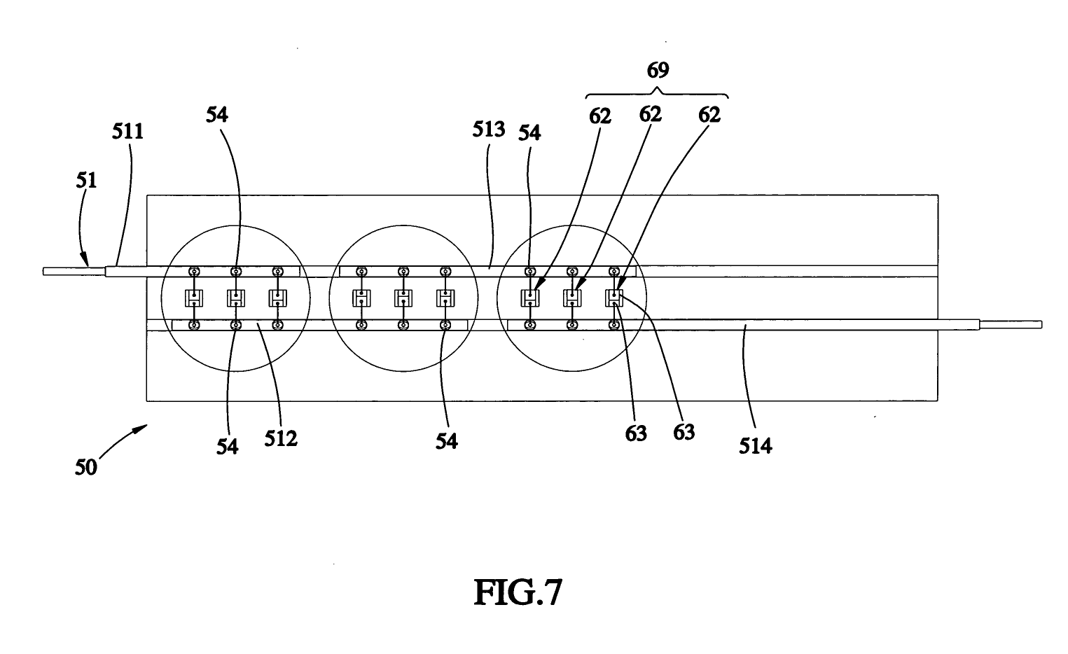

FIGS. 6 and 7 show an LED and thermal conductivity device combination assembly 50 in accordance with a second embodiment of the present invention. This second embodiment is substantially similar to the aforesaid first embodiment with the exception that the LED chips 62 are arranged into multiple LED parallel sets 69. Each LED parallel set 69 is comprised of multiple, for example, three LED chips 62 that are connected in parallel. The positive and negative electrodes 63 of the first one of the LED parallel sets 69 are respectively connected to the metal conducting wire 54 of the first conducting member 511 and the metal conducting wire 54 of the second conducting member 512. The positive and negative electrodes 63 of the second one of the LED parallel sets 69 are respectively connected to the metal conducting wire 54 of the second conducting member 512 and the metal conducting wire 54 of the third conducting member 513. The positive and negative electrodes 63 of the third one of the LED parallel sets 69 are respectively connected to the metal conducting wire 54 of the third conducting member 513 and the metal conducting wire 54 of the fourth conducting member 514. Therefore, the LED parallel sets 69 are connected in series, i.e., the LED chips 62 of this second embodiment has a series connection configuration and a parallel connection configuration.

The aforesaid second embodiment is simply an example of the present invention, the number of the LED parallel sets 69 is not a limitation, i.e., other number of LED parallel sets 69 can be connected in series.

As stated above, the invention achieves the effect of quick transfer of heat energy and the effect of reduction of the demand for power. By means of directly bonding the LED chips 32 to the surface of the thermal conductivity device 11, heat is rapidly transferred to the thermal conductivity device 11 for quick dissipation during operation of the LED chips 32. Further, using the conducting members 21 to connect the LED series sets 39 in parallel, lowers the requirement for power specification, i.e., the invention allows LED chips to be connected in series and in parallel, fitting power specification requirements.

What is claimed is:

1. AN LED and thermal conductivity device combination assembly comprising:
a thermal conductivity device;
at least one pair of conducting members, said conducting members each comprising a metal conducting wire and an insulator, said insulator being attached to said thermal conductivity device to insulate said metal conducting wire from said thermal conductivity device;
a plurality of LED units, said LED units each comprising an LED chip, the LED chip of each of said LED units comprising a positive electrode and a negative electrode disposed at a top side thereof and an insulation layer disposed at a bottom side thereof and bonded to the surface of said thermal conductivity device;
a plurality of lead wires connected between the positive electrode and negative electrode of the LED chip of each of said LED units and the metal conducting wires of said conducting members to connect the LED chips of said LED units in series and in parallel; and
at least one packaging device covering said LED units.

2. The LED and thermal conductivity device combination assembly as claimed in claim 1, wherein the bottom insulation layer of the LED chip of each of said LED units is respectively bonded to the surface of said thermal conductivity device with a thermal conductivity layer.

3. The LED and thermal conductivity device combination assembly as claimed in claim 2, wherein said thermal conductivity layer is selected from one of solder paste and epoxy resin.

4. The LED and thermal conductivity device combination assembly as claimed in claim 1, wherein the insulator of each of said conducting members surrounds the associating metal conducting wire.

5. The LED and thermal conductivity device combination assembly as claimed in claim 4, wherein said lead wires connect the LED chips of said LED units into multiple LED series sets by means of connecting the positive electrode of the LED chip of one of said LED units to the negative electrode of the LED chip of another of said LED units to connect the LED chips of said LED units in series; said conducting members each have a plurality of openings through which said lead wires are connected to the metal conducting wires of said conducting members.

6. The LED and thermal conductivity device combination assembly as claimed in claim 5, wherein said LED series sets are connected in parallel by said lead wires in which a manner that the positive electrodes of the LED chips of said LED series sets are connected to the metal conducting wire of one of each pair of said conducting members by said lead wires and the negative electrodes of the LED chips of said LED series sets are connected to the metal conducting wire of the other of each pair of said conducting members by said lead wires.

7. The LED and thermal conductivity device combination assembly as claimed in claim 1, wherein said thermal conductivity device has two grooves that accommodate said at least one pair of conducting members.

8. The LED and thermal conductivity device combination assembly as claimed in claim 7, wherein said thermal conductivity device is a heat sink, comprising a thermal transfer plate and a plurality of radiation fins arranged on a top side of said thermal transfer plate; said two grooves are arranged on a bottom side of said thermal transfer plate opposite to said radiation fins.

9. The LED and thermal conductivity device combination assembly as claimed in claim 1, wherein said at one packaging device covers said at least one pair of conducting members partially.

10. The LED and thermal conductivity device combination assembly as claimed in claim 1, wherein said at least one pair of conducting members are respectively formed of a respective circuit board; the insulator of each of said conducting members is prepared from epoxy resin; the metal conducting wire of each of said conducting members is prepared from a copper foil on the circuit board of the respective conducting member.

11. The LED and thermal conductivity device combination assembly as claimed in claim 1, wherein said at least one pair of conducting members include a first conducting member, a second conducting member, a third conducting member, and a fourth conducting member; said lead wires connect the LED chips of said LED units into multiple LED parallel sets in such a manner that the positive and negative electrodes of the first one of said LED parallel sets are respectively connected to the metal conducting wire of said first conducting member and the metal conducting wire of said second conducting member, the positive and negative electrodes of the second one of the LED parallel sets are respectively connected to the metal conducting wire of said second conducting member and the metal conducting wire of said third conducting member, and the positive and negative electrodes of the third one of said LED parallel sets are respectively connected to the metal conducting wire of said third conducting member and the metal conducting wire of said fourth conducting member.
